(19) United States
(12) Patent Application Publication
(10) Pub. No.: US 2010/0164106 A1
(43) Pub. Date: Jul. 1, 2010

(54) CMP Slurry Composition for Barrier Polishing for Manufacturing Copper Interconnects, Polishing Method Using the Composition, and Semiconductor Device Manufactured by the Method

(75) Inventors: Tae Young LEE, Uiwang-si (KR); In Kyung LEE, Uiwang-si (KR); Byoung Ho CHOI, Uiwang-si (KR); Yong Soon PARK, Uiwang-si (KR)

Correspondence Address: SUMMA, ADDITON & ASHE, P.A., 11610 NORTH COMMUNITY HOUSE ROAD, SUITE 200, CHARLOTTE, NC, 28277, US

(73) Assignee: Cheil Industries Inc., Gumi-si (KR)

(21) Appl. No.: 12/647,612

(22) Filed: Dec. 28, 2009

(30) Foreign Application Priority Data
Dec. 31, 2008 (KR) 10-2008-0137804
Sep. 15, 2009 (KR) 10-2009-0086869

(51) Int. Cl. H01L 23/52; H01L 21/306; C09K 13/06

(52) U.S. Cl. 257/751; 438/693; 252/79.1; 252/79.4; 257/E23.141; 257/E21.23

(57) ABSTRACT

Provided is a CMP slurry composition for barrier polishing for manufacturing copper interconnects, the composition including abrasive particles, a copper surface protective agent, a copper corrosion inhibitor, an oxidizing agent, and a pH adjustor, wherein the abrasive particles are non-spherical colloidal silica having a ratio of an average primary particle size to an average secondary particle size of about 0.6 or less and the copper surface protective agent is a carboxyl-functionalized water-soluble polymer.

### CROSS-REFERENCE TO RELATED APPLICATIONS

This application claims the priority of Korean Patent Application No. 10-2008-0137804, filed on Dec. 31, 2008, and No. 10-2009-0086869, filed on Sep. 15, 2009, in the Korean Intellectual Property Office, the disclosures of each of which are incorporated herein in their entireties by reference.

### FIELD OF THE INVENTION

The present invention relates to a chemical-mechanical polishing (CMP) slurry composition for barrier polishing for manufacturing copper interconnects

### BACKGROUND OF THE INVENTION

With recent trends toward high integration and high performance of large-scale integrated circuits (hereinafter, referred to as LSIs), new micro-processing methods have been developed. Chemical-mechanical polishing (hereinafter, referred to as CMP), which is one of such methods, is a technique used frequently in processes for manufacturing LSIs, particularly in processes for manufacturing multilayered metal interconnects, to planarize inter-insulating layers, to form metal plugs or embedded metal interconnects, or the like. Recently, copper or copper alloy has been used as an interconnect material in order to manufacture highly integrated LSIs. However, copper and copper alloys are difficult to process using dry etching that has been frequently used in the formation of aluminum alloy interconnects. In this regard, a damascene process is used in which a copper or a copper alloy thin film is deposited and embedded on and into an insulating film with trenches formed thereon and thin film portions other than the trenches are then removed by CMP, thereby forming embedded copper interconnects.

CMP is a process of planarizing a wafer surface using a polishing pad and a slurry composition during the fabrication of semiconductor devices. During CMP, a wafer undergoes an orbital motion (combination of rotational motion and linear motion) relative to a polishing pad in a state where the wafer and the polishing pad are contacted to each other, and at this time, polishing is performed using a slurry composition including abrasive particles. Generally, a slurry composition used in CMP includes abrasive particles responsible for physical action and an etchant responsible for chemical action. Thus, a CMP slurry composition can remove selectively an exposed portion on a wafer surface by physical and chemical actions, thereby ensuring optimized planarization over a wide surface area.

When forming metal interconnects using CMP, it is important to realize a desired polishing rate while controlling chemical etching. In particular, in the formation of copper interconnects, a copper film can be easily removed due to high corrosion property to chemical materials, but copper interconnects may be easily corroded due to an increased etching rate. In view of this problem, an appropriate concentration of an oxidizing agent should be used, and at the same time, the addition of a corrosion inhibitor to a CMP slurry composition is needed.

For the formation of embedded metal interconnects, e.g., copper or copper alloy interconnects or tungsten-plug interconnects, three-step polishing is performed as follows. For example, for the formation of copper interconnects, first, bulky copper is rapidly removed (so-called “bulk copper polishing step”). Second, copper is removed but a barrier film and an insulating film are not removed (so-called “copper over-polishing step”). Third, the removal rate of copper is decreased and the removal rates of the barrier film and the insulating films are increased so that the removal rate of copper is substantially the same as those of the barrier film and the insulating film (so-called “barrier polishing step”). That is, the polishing selectivity of copper relative to the barrier film and the insulating film should be lowered in order to reduce erosion/dishing occurred during the second polishing step and to completely remove a copper residue. If the polishing rates of the barrier film and the insulating film are remarkably lower than that of copper, erosion/dishing occurred during the second polishing step may not be eliminated.

Generally, the first and second polishing steps are performed using the same bulk copper polishing slurry composition under different polishing conditions. The third polishing step is performed using a barrier polishing slurry composition which is different from the bulk copper polishing slurry composition. The present invention provides a slurry composition for the third polishing step.

For the formation of copper interconnects, tantalum, tantalum alloy, tantalum nitride, or other tantalum compounds are used as barrier materials for preventing the diffusion of copper into an inter-insulating layer. These barrier materials have higher rigidity than copper and copper alloys and tend not to be easily oxidized. Thus, generally the removal rate of barrier materials using a mechanical method is increased. In this case, however, there is a higher likelihood to cause scratches on pattern surfaces after polishing.

In order to improve the removal of dishing and erosion on final copper interconnect patterns, during a barrier polishing step, the polishing rate ratio of a copper film, a barrier film and an insulating film is ideally 1:1:1, and after final polishing, surface defects such as contamination or scratches due to residual abrasive particles left on the insulating film and copper interconnects are at a level as low as possible.

### SUMMARY OF THE INVENTION

The present invention provides a CMP slurry composition for barrier polishing for manufacturing copper interconnects, which can realize a high polishing rate for tantalum used as a barrier material and silicon oxide used as an insulating material so that the polishing rate ratio of tantalum, silicon oxide, and copper is about 1:1:1 (non-selective polishing).

The present invention also provides a method for non-selectively polishing a barrier film, an insulating film and a copper film at high rates using the above-described CMP slurry composition, thereby minimizing surface defects after final polishing, and a semiconductor device manufactured by the method.

According to an aspect of the present invention, there is provided a CMP slurry composition for barrier polishing for manufacturing copper interconnects, the composition including abrasive particles, a copper surface protective agent, a copper corrosion inhibitor, an oxidizing agent, and a pH adjustor, wherein the abrasive particles are non-spherical colloidal silica having a ratio of an average primary particle size to an average secondary particle size of about 0.6 or less and the copper surface protective agent is a carboxyl-functionalized water-soluble polymer.

The composition may perform non-selective polishing such that the polishing rate ratio of a barrier film, an insulating film and a copper film with respect to each other is a range from about 0.8 to about 1.2.

The colloidal silica may have an average primary particle size of about 20 to about 60 nm and an average secondary particle size of about 34 to about 200 nm, and may be used in an amount of about 0.5 to about 30 wt % based on the total weight of the CMP slurry composition.

The copper surface protective agent may be used in an amount of about 0.01 to about 3 wt % based on the total weight of the CMP slurry composition, and may include at least one material selected from the group consisting of polycarboxylic acids, polyacrylic acid-co-organic acids and about 60% or more carboxyl-functionalized polycarboxylic acid-co-amides.

The copper surface protective agent may be at least one selected from the group consisting of polyacrylic acids, polybutadiene-co-maleic acids, polymaleic acids, polymethacrylic acids, polyacrylic acid-co-maleic acids, and polyacrylamide-co-acylic acids.

The oxidizing agent may be at least one selected from the group consisting of inorganic or organic per-compounds, bromic acids and salts thereof, nitric acids and salts thereof, chloric acids and salts thereof, chromic acids and salts thereof, iodic acids and salts thereof, iron and salts thereof, copper and salts thereof, rare earth metal oxides, transition metal oxides, potassium ferricyanides, and potassium bichromates, and may be used in an amount of about 0.01 to about 1.5 wt % based on the total weight of the CMP slurry composition.

The copper corrosion inhibitor may be at least one selected from the group consisting of 5-methyl-1H-benzotriazols, 2,2′-[[(5-methyl-1H-benzotriazole-1-yl)-methyl]imino]bis-ethanols, 1,2,4-triazoles, 1,2,3-triazoles and 1,2,3-triazolo[4,5-b]pyridines, and may be used in an amount of about 0.001 to about 1 wt % based on the total weight of the CMP slurry composition.

According to another aspect of the present invention, there is provided a method of polishing a barrier film for manufacturing copper interconnects using the above-described CMP slurry composition.

According to still another aspect of the present invention, there is provided a semiconductor device including copper interconnects manufactured by the above-described method.

As described above, the inventive CMP slurry composition can realize a high polishing rate for tantalum used as a barrier material and silicon oxide used as an insulating material so that the polishing rate ratio of a tantalum film, a silicon oxide film, and a copper film with respect to each other is in a range from about 0.8 to about 1.2, thereby minimizing surface defects after final polishing, and thus, is very useful for barrier polishing for manufacturing copper interconnects.

### DETAILED DESCRIPTION OF THE INVENTION

The present invention now will be described more fully hereinafter in the following detailed description of the invention, in which some, but not all embodiments of the invention are described. Indeed, this invention may be embodied in many different forms and should not be construed as limited to the embodiments set forth herein; rather, these embodiments are provided so that this disclosure will satisfy applicable legal requirements.

The terminology used herein is for the purpose of describing particular embodiments only and is not intended to be limiting of the invention. As used herein the term “and/or” includes any and all combinations of one or more of the associated listed items. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The present invention provides a CMP slurry composition for barrier polishing for manufacturing copper interconnects, the composition including abrasive particles, a copper surface protective agent, a copper corrosion inhibitor, an oxidizing agent, and a pH adjustor, wherein the abrasive particles are non-spherical colloidal silica having a ratio of an average primary particle size to an average secondary particle size of about 0.6 or less and the copper surface protective agent is a carboxyl-functionalized water-soluble polymer.

The present invention will now be described more fully hereinafter.

The colloidal silica is a material used to provide an enhanced dispersion stability under acidic conditions, to reduce copper polishing rate with no scratches and to increase the polishing rates for a barrier film and an insulating film so that the polishing rate ratio of the copper film, the barrier film and the insulating film with respect to each other is substantially the same. The colloidal silica may have a ratio of an average primary particle size (D1) to an average secondary particle size (D2) of about 0.6 or less, for example from about 0.3 to about 0.6. Although a smaller D1/D2 ratio provides a better polishing efficiency, a D1/D2 ratio ranging from about 0.3 to about 0.6 is used on a commercial scale. As well known in the art, the particle size (diameter) of metal oxide can be divided into two types, i.e., a primary particle size (diameter) and a secondary particle size (length). Generally, a primary particle size means the size (diameter) of an individual spherical metal oxide particle measured by BET (Brunauer-Emmett-Teller) or TEM (Transmission Electron Microscopic) analysis before preparing a slurry composition, and a secondary particle size means the size (length) of a non-spherical particle cluster measured by DLS (dynamic laser scattering) analysis after preparing a slurry composition. The colloidal silica may have an average primary particle size of about 20 to about 60 nm and an average secondary particle size of about 34 to about 200 nm.

The colloidal silica may be used in an amount of about 0.5 to about 30 wt %, for example about 1 to about 20 wt %, and as another example about 5 to about 10 wt %, based on the total weight of the CMP slurry composition, which can provide an appropriate polishing rate and good slurry dispersion stability.

The copper surface protective agent is responsible for adjusting a copper polishing rate to an appropriate level with no occurrence of copper pitting, by acting on a copper surface competitively with the corrosion inhibitor. The copper surface protective agent may be an anionic carboxyl-functionalized water-soluble polymer having a weight average molecular weight (Mw) of about 500,000 or less. The copper surface protective agent may be selected from polycarboxylic acids (e.g., polyacrylic acid), acrylic acid-co-organic acids (e.g., acrylic acid-co-maleic acid), carboxylic acid-co-amides, and combinations thereof. With respect to carboxylic acid-co-amides, the relative distribution (ratio) of carboxyl functional groups to amide functional groups may be about 60% or more. This is because more cationic amide functional groups may lead to a reduced removal rate of a barrier film and less storage stability of the slurry composition.

Exemplary polycarboxylic acids may include without limitation polyacrylic acids, polybutadiene-co-maleic acids, polymaleic acids, polymethacrylic acids, and the like, and combinations thereof, exemplary acrylic acid-co-organic acids may include without limitation polyacrylic acid-co-maleic acids, and the like, and combinations thereof, and exemplary carboxylic acid-co-amides may include without limitation polyacrylamide-co-acylic acids, and the like, and combinations thereof.

The copper surface protective agent may be used in an amount of about 0.01 to about 3 wt %, for example about 0.02 to about 2 wt %, and as another example about 0.05 to about 1 wt % based on the total weight of the CMP slurry composition, which can provide an appropriate polishing rate and good slurry dispersion stability.

The oxidizing agent as used herein serves to oxidize a metal surface, thereby ensuring an enhanced polishing rate. Exemplary oxidizing agents may include without limitation inorganic or organic per-compounds, bromic acids and salts thereof, nitric acids and salts thereof, chloric acids and salts thereof, chromic acids and salts thereof, iodic acids and salts thereof, iron and salts thereof, copper and salts thereof, rare earth metal oxides, transition metal oxides, potassium ferricyanides, potassium bichromates, and the like and combinations thereof. Hydrogen peroxide can result in less environmental contamination.

The oxidizing agent may be used in an amount of about 0.01 to about 1.5 wt %, for example about 0.05 to about 1 wt %, and as another example about 0.1 to about 0.5 wt % based on the total weight of the CMP slurry composition, which can provide an appropriate polishing rate and good surface properties of a polished surface.

The copper corrosion inhibitor is a material used to retard the chemical reaction of the oxidizing agent. In detail, the copper corrosion inhibitor serves as a polishing adjustor which inhibits copper corrosion at a lower topographic area on which physical polishing does not occur and which is removed at a higher topographic area by physical action of the abrasive particles. The copper corrosion inhibitor may be mainly selected from nitrogen-containing compounds, e.g., ammonia, alkylamines, amino acids, imines, azoles, and the like, and combinations of two or more. Exemplary copper corrosion inhibitors can include without limitation cyclic nitrogen compounds or derivatives thereof, for example, benzotriazoles or derivatives thereof, and as further examples, isomeric mixtures of 5-methyl-1H-benzotriazoles, isomeric mixtures of 2,2′-[[(5-methyl-1H-benzotriazole-1-yl)-methyl]imino]bis-ethanols, 1,2,4-triazoles, 1,2,3-triazoles, or 1,2,3-triazolo[4,5-b]pyridines.

The corrosion inhibitor may be used in an amount of about 0.001 to about 1 wt %, for example about 0.005 to about 0.1 wt %, and as another example about 0.01 to about 0.07 wt % based on the total weight of the CMP slurry composition, which can provide a good corrosion inhibition effect, an appropriate polishing rate and good slurry storage stability.

The inventive CMP slurry composition may include a pH adjustor commonly used in the art in order to adjust the pH of the slurry composition to a range from about 2.0 to about 4.5. In addition, the CMP slurry composition may further include additives such as a surfactant commonly used in the art.

The polishing of a barrier film using the inventive CMP slurry composition will now be simply described. A first polishing step is performed using a bulk copper polishing slurry composition commonly known in the art to rapidly remove excess copper. Then, a second polishing step is performed using the same bulk copper polishing slurry composition as in the first polishing step except that a lower down force is applied and a barrier film and an insulating film are not removed while removing copper. Finally, copper, the barrier film and the insulating film are removed at substantially the same rates using the inventive CMP slurry composition to thereby reduce erosion/dishing occurred on the barrier film and the insulating film during the second polishing step and to completely remove a copper residue.

Thus, the present invention provides a method of polishing a barrier film for manufacturing copper interconnects using the above-described CMP slurry composition.

The present invention also provides a method of manufacturing copper interconnects, the method comprising: polishing a copper film on a surface of a wafer having thereon the copper film, a barrier film, and an insulating film, using a copper polishing slurry composition known in the art under a higher down force; polishing a residual copper film on the surface of the wafer using the same copper polishing slurry composition as above under a lower down force; and polishing the barrier film, the insulating film and embedded copper at substantially the same rates using the above-described inventive slurry composition, and a semiconductor device including copper interconnects manufactured by the above method.

As described above, the inventive CMP slurry composition is effective for barrier polishing for manufacturing copper interconnects, and thus, is useful for manufacturing semiconductor devices, involving a barrier polishing step.

Hereinafter, the present invention will be described with reference to the following examples but is not limited thereto.

### Examples 1 to 4

First, 0.5 wt of colloidal silica (particle size: 20 nm), 0.5 wt % of glycine, and 0.1 wt % of benzotriazole (BTA) are mixed with pure water to prepare a slurry precursor composition for bulky copper polishing. The slurry precursor composition is adjusted to have pH 7.0 using KOH and nitric acid, mixed with 1.0 wt % of hydrogen perperoxide and stirred for 10 minutes immediately before polishing to complete a copper polishing slurry composition. Then, wafers having thereon a copper film, a tantalum film and a TEOS (tetraethyl orthosilicate) film are subjected to a first polishing step and a second polishing step, sequentially, using the resultant slurry composition, respectively, under the conditions of a down force of 2.5 psi, a platen rotation rate of 93 rpm, a head rotation rate of 87 rpm, and a slurry feed rate of 150 ml/min and under the conditions of a down force of 1.5 psi, a platen rotation rate of 93 rpm, a head rotation rate of 87 rpm, and a slurry feed rate of 150 ml/min.

As presented in Table 1 below, 8 wt % of colloidal silica, 0.045 wt % of 5-methyl-1H-benzotriazole (TTA) used as a corrosion inhibitor, 0.2 wt % of hydrogen peroxide, 0.1 wt % of a copper surface protective agent and 91.65 wt % of deionized water are mixed to prepare slurry compositions for barrier polishing. The slurry compositions are adjusted to have pH 2.9-3.0 using a small amount of nitric acid. The third polishing step is performed on the wafers treated with the first and second polishing steps using each of the barrier polishing slurry compositions under the following conditions. Copper etching rates and polishing performance are evaluated and the results are summarized in Table 2 below.

For evaluation of copper etching rates, a copper specimen (3×3 cm) is incubated in a beaker containing 10 g of each of the barrier polishing slurry compositions at 25° C. for 30 minutes, and the thickness of the copper specimen before and after etching is measured.

For evaluation of polishing performance, embedded copper, the tantalum film and the TEOS film are removed under the conditions of a platen rotation rate of 93 rpm, a head rotation rate of 87 rpm, a down force of 1.5 psi, a slurry feed rate of 150 ml/min, for 60 seconds, using the 200 mm Applied Mirra Mesa CMP system (AMAT). An IC1010 polishing pad (Rodel) is used. A film thickness difference before and after polishing is converted to electric resistance to obtain a polishing rate.

The degree of surface defects is evaluated for copper and the TEOS film. For copper surface, 0.247 μm or more sized defects are counted, and for TEOS surface, 0.09 μm or more sized defects are counted.

### Comparative Examples 1 to 6

Polishing performance is evaluated in the same manner as in Example 1 except that copper surface protective agents and the particle distribution of abrasive particles are as presented in Table 1 below, and the results are summarized in Table 2 below.

TABLE 1

| | Copper | Corrosion | | Abrasive particles | | | |
|---|---|---|---|---|---|---|---|
| | surface | inhibitor | | Average primary | Average secondary | | |
| | protective | (TTA) | H₂O₂ | particle size | particle size (D2) | | |
| Sample | agent | (wt %) | (wt %) | (D1) (±3 nm) | (±5 nm) | D1/D2 | pH |
| Example 1 | PAA | 0.045 | 0.2 | 25 | 41 | 0.6 | 2.97 |
| Example 2 | PAA | 0.045 | 0.2 | 35 | 90 | 0.4 | 3.02 |
| Example 3 | PAA/MA (1:1) | 0.045 | 0.2 | 25 | 50 | 0.5 | 2.97 |
| Example 4 | PAM/AA (4:6) | 0.045 | 0.2 | 25 | 50 | 0.5 | 2.97 |
| Comparative | PAA | 0.045 | 0.2 | 20 | 25 | 0.8 | 2.98 |
| Example 1 | | | | | | | |
| Comparative | PAA | 0.045 | 0.2 | 50 | 55 | 0.9 | 3.01 |
| Example 2 | | | | | | | |
| Comparative | PAA | 0.045 | 0.2 | 70 | 75 | 0.9 | 2.99 |
| Example 3 | | | | | | | |
| Comparative | PAM | 0.045 | 0.2 | 25 | 50 | 0.5 | 3.01 |
| Example 4 | | | | | | | |
| Comparative | PAM/AA (6:4) | 0.045 | 0.2 | 25 | 50 | 0.5 | 2.97 |
| Example 5 | | | | | | | |
| Comparative | — | 0.045 | 0.2 | 25 | 50 | 0.5 | 2.98 |
| Example 6 | | | | | | | |

PAA: polyacrylic acid
PAM: polyacrylic amide
PAA/MA: polyacrylic acid-co-maleic acid
PAM/AA: polyacrylic amide-co-acrylic acid

TABLE 2

| | | | | | | The number of | |
|---|---|---|---|---|---|---|---|
| | Copper | | | | Polishing | surface defects | |
| | etching rate | Polishing rate (Å/min) | | | rate ratio | >0.247 μm | >0.09 μm |
| Sample | (Å/min) | Tantalum | TEOS | Copper | Ta:TEOS:Cu | (Cu) | (TEOS) |
| Example 1 | 8.2 | 601 | 550 | 542 | 1.1:1:1 | 96 | 113 |
| Example 2 | 8.4 | 576 | 640 | 654 | 0.9:1:1 | 93 | 124 |
| Example 3 | 8.1 | 605 | 560 | 534 | 1.1:1:1 | 75 | 98 |
| Example 4 | 8.3 | 521 | 550 | 539 | 1:1:1 | 92 | 116 |
| Comparative | 8.1 | 364 | 150 | 1423 | 0.3:0.1:1 | 138 | 562 |
| Example 1 | | | | | | | |
| Comparative | 7.8 | 353 | 199 | 1362 | 0.3:0.2:1 | 157 | 457 |
| Example 2 | | | | | | | |
| Comparative | 8.2 | 262 | 241 | 717 | 0.4:0.3:1 | 113 | 519 |
| Example 3 | | | | | | | |
| Comparative | 9.5 | 145 | 547 | 326 | 0.4:1.7:1 | 95 | 120 |
| Example 4 | | | | | | | |
| Comparative | 8.5 | 254 | 642 | 650 | 0.4:1:1 | 124 | 126 |
| Example 5 | | | | | | | |
| Comparative | 6.0 | 596 | 553 | 198 | 3:2.8:1 | 87 | 1565 |
| Example 6 | | | | | | | |

As presented in Tables 1 and 2, according to the inventive CMP slurry compositions, tantalum films and oxide films exhibit high polishing rates, and the polishing rate ratio of the tantalum film, the oxide film and copper is about 1:1:1 (non-selective polishing). The expression “non-selective polishing” or its similar expression as used herein is intended to mean that the polishing rate ratio of a barrier film, an insulating film and a copper film with respect to each other is 1.0±0.20 (i.e., 0.80 to 1.20).

The inventive CMP slurry compositions of Examples 1-4, wherein abrasive particles with a D1/D2 ratio of 0.4 to 0.6 are used and a polyacrylic acid, a copolymer of an acrylic acid and a maleic acid (1:1), or a copolymer of an acrylamide and an acrylic acid (4:6) are used as a copper surface protective agent, achieve desired polishing performance.

In connection with the CMP slurry compositions of Comparative Examples 1-3 wherein abrasive particles with a D1/D2 ratio of 0.8 to 0.9 are used and a polyacrylic acid is used as a copper surface protective agent, the tantalum film and the TEOS film exhibit lower polishing rates. In connection with the CMP slurry compositions of Comparative Examples 4-5 wherein abrasive particles with a D1/D2 ratio of 0.5 are used, and polyacrylamide or a copolymer of acrylmide and an acrylic acid (6:4) are used as a copper surface protective agent, the polishing rate of the tantalum film is lowered relative to the TEOS film and copper, which makes it difficult to accomplish a polishing rate ratio of a tantalum film, an oxide film and a copper film of about 1:1:1 (non-selective polishing).

In connection with the CMP slurry composition of Comparative Example 6 containing no copper surface protective agent, copper polishing did not occur efficiently due to excessive reaction of the corrosion inhibitor on copper surface. In this regard, an adjustment of the content of the corrosion inhibitor can be considered, but such an adjustment caused the severe variation of a copper polishing rate, thereby resulting in inappropriate copper removal.

Pattern evaluation is performed using the CMP slurry composition of Example 3 under the same polishing conditions as described above. The results are presented in Table 3 below. Dishing phenomena are measured in areas of copper and oxide lines with a line width of 100 μm, and erosion phenomena are measured in 90% pattern density areas of copper lines with a line width of 9 μm and oxide lines with a line width of 1 μm.

TABLE 3

| | | Degree (Å) | | Degree (Å) |
|---|---|---|---|---|
| | Dishing | of dishing | | of dishing |
| | (Å) | improvement | Erosion (Å) | improvement |
| Initial | 600 | — | 550 | — |
| Polishing for 60 sec | 380 | 220 | 392 | 158 |
| Polishing for | 185 | 415 | 211 | 339 |
| 120 sec | | | | |
| Polishing for | 28 | 572 | 40 | 510 |
| 180 sec | | | | |

As presented in Table 3, the inventive CMP slurry composition significantly improved dishing and erosion problems after final polishing, and the dishing of the insulating film is significantly reduced at an erosion area.

As described above, the inventive CMP slurry composition can realize a high polishing rate for tantalum used as a barrier material and silicon oxide used as an insulating material so that the polishing rate ratio of tantalum, silicon oxide and copper with respect to each other is in a range from about 0.8 to about 1.2, i.e., about 1:1:1 (non-selective polishing), thereby minimizing surface defects after final polishing, and thus, can be very useful for barrier polishing for manufacturing copper interconnects.

Many modifications and other embodiments of the invention will come to mind to one skilled in the art to which this invention pertains having the benefit of the teachings presented in the foregoing descriptions. Therefore, it is to be understood that the invention is not to be limited to the specific embodiments disclosed and that modifications and other embodiments are intended to be included within the scope of the appended claims. Although specific terms are employed herein, they are used in a generic and descriptive sense only and not for purposes of limitation, the scope of the invention being defined in the claims.

What is claimed is:

1. A CMP slurry composition for barrier polishing for manufacturing copper interconnects, the composition comprising abrasive particles, a copper surface protective agent, a copper corrosion inhibitor, an oxidizing agent, and a pH adjustor,
wherein the abrasive particles are non-spherical colloidal silica having a ratio of an average primary particle size to an average secondary particle size of about 0.6 or less and the copper surface protective agent is a carboxyl-functionalized water-soluble polymer.

2. The CMP slurry composition of claim 1, which performs non-selective polishing such that the polishing rate ratio of a barrier film, an insulating film and a copper film with respect to each other ranges from about 0.8 to about 1.2.

3. The CMP slurry composition of claim 1, wherein the colloidal silica has an average primary particle size of about 20 to about 60 nm and an average secondary particle size of about 34 to about 200 nm, and is used in an amount of about 0.5 to about 30 wt % based on the total weight of the CMP slurry composition.

4. The CMP slurry composition of claim 1, wherein the copper surface protective agent is used in an amount of about 0.01 to about 3 wt % based on the total weight of the CMP slurry composition.

5. The CMP slurry composition of claim 1, wherein the copper surface protective agent comprises polycarboxylic acid, polyacrylic acid-co-organic acid, about 60% or more carboxyl-functionalized polycarboxylic acid-co-amide, or a combination thereof.

6. The CMP slurry composition of claim 1, wherein the copper surface protective agent comprises polyacrylic acid, polybutadiene-co-maleic acid, polymaleic acid, polymethacrylic acid, polyacrylic acid-co-maleic acid, polyacrylamide-co-acylic acid, or a combination thereof.

7. The CMP slurry composition of claim 1, wherein the oxidizing agent comprises an inorganic per-compound, an organic per-compound, bromic acid, a salt of bromic acid, nitric acid, a salt of nitric acid, chloric acid, a salt of chloric acid, chromic acid, a salt of chromic acid, iodic acid, a salt of iodic acid, iron, a salt of iron, copper, a salt of copper, rare earth metal oxide, transition metal oxide, potassium ferricyanide, potassium bichromate, or a combination thereof and is used in an amount of about 0.01 to about 1.5 wt % based on the total weight of the CMP slurry composition.

8. The CMP slurry composition of claim 1, wherein the copper corrosion inhibitor comprises 5-methyl-1H-benzotriazol, 2,2′-[[(5-methyl-1H-benzotriazole-1-yl)-methyl]imino]bis-ethanol, 1,2,4-triazoles, 1,2,3-triazole, 1,2,3-triazolo[4,5-b]pyridine, or a combination thereof and is used in an amount of about 0.001 to about 1 wt % based on the total weight of the CMP slurry composition.

9. A method of polishing a barrier film for manufacturing copper interconnects using a CMP slurry composition comprising abrasive particles, a copper surface protective agent, a copper corrosion inhibitor, an oxidizing agent, and a pH adjustor, wherein the abrasive particles are non-spherical colloidal silica having a ratio of an average primary particle size to an average secondary particle size of about 0.6 or less and the copper surface protective agent is a carboxyl-functionalized water-soluble polymer.

10. The method of claim 9, wherein comprises polishing a barrier film, an insulating film and a copper film at a polishing rate ratio ranging from about 0.8 to about 1.2 with respect to each other.

11. The method of claim 9, wherein the colloidal silica has an average primary particle size of about 20 to about 60 nm and an average secondary particle size of about 34 to about 200 nm, and is used in an amount of about 0.5 to about 30 wt % based on the total weight of the CMP slurry composition.

12. The method of claim 9, wherein the copper surface protective agent is used in an amount of about 0.01 to about 3 wt % based on the total weight of the CMP slurry composition.

13. The method of claim 9, wherein the copper surface protective agent comprises polycarboxylic acid, polyacrylic acid-co-organic acid, about 60% or more carboxyl-functionalized polycarboxylic acid-co-amide, or a combination thereof.

14. The method of claim 9, wherein the copper surface protective agent comprises polyacrylic acid, poly butadiene-co-maleic acid, polymaleic acid, polymethacrylic acid, polyacrylic acid-co-maleic acid, polyacrylamide-co-acylic acid, or a combination thereof.

15. The method of claim 9, wherein the oxidizing agent comprises an inorganic or organic per-compound, bromic acid, a salt of bromic acid, nitric acid, a salt of nitric acid, chloric acid, a salt of chloric acid, chromic acid, a salt of chromic acid, iodic acid, a salt of iodic acid, iron, a salt of iron, copper, a copper salt, rare earth metal oxide, transition metal oxide, potassium ferricyanide, and potassium bichromate, or a combination thereof and is used in an amount of about 0.01 to about 1.5 wt % based on the total weight of the CMP slurry composition.

16. A semiconductor device comprising copper interconnects manufactured by the method of claim 9.
